(19) United States
(12) Patent Application Publication
(10) Pub. No.: US 2016/0260712 A1
(43) Pub. Date: Sep. 8, 2016

(54) SEMICONDUCTOR DEVICE AND MANUFACTURING METHOD THEREOF

(71) Applicant: KABUSHIKI KAISHA TOSHIBA, Minato-ku (JP)

(72) Inventor: Atsushi YAGISHITA, Yokohama (JP)

(73) Assignee: KABUSHIKI KAISHA TOSHIBA, Minato-ku (JP)

(21) Appl. No.: 14/847,353

(22) Filed: Sep. 8, 2015

Related U.S. Application Data
(60) Provisional application No. 62/129,535, filed on Mar. 6, 2015.

(51) Int. Cl. H01L 27/088; H01L 29/66; H01L 21/265; H01L 23/535; H01L 21/768; H01L 29/423; H01L 29/78; H01L 29/06

(52) U.S. Cl. CPC H01L 27/088; H01L 29/7833; H01L 29/66575; H01L 29/0649; H01L 23/535; H01L 21/76897; H01L 29/42364; H01L 21/26513

(57) ABSTRACT

A semiconductor device has two first semiconductor regions that are arranged at intervals on a surface of a semiconductor substrate, one of the two semiconductor regions being a source region and another of the two semiconductor regions being a drain region, and a contact that extends from at least one of the two first semiconductor regions on the semiconductor substrate. The contact comprises a single-crystal first semiconductor layer arranged to contact the surface of the semiconductor substrate, a compound layer that is arranged on the first semiconductor layer and includes a semiconductor in the first semiconductor layer and a metal, and a metal layer arranged on the compound layer.

### CROSS REFERENCE TO RELATED APPLICATIONS

This application is based upon and claims the benefit of priority from the prior U.S. Provisional Patent Application No. 62/129,535 filed on Mar. 6, 2015, the entire contents of which are incorporated herein by reference.

### FIELD

The present invention relates to a semiconductor device and a method of manufacturing the same.

### BACKGROUND

In a NAND-type flash memory, a high breakdown voltage transistor and a low breakdown voltage transistor are necessary.

In the high breakdown voltage transistor, it is necessary to maximize a distance from a gate end portion to a boundary position of an N− region and an N+ region in a source/drain region, a distance from an end portion of the N+ region to an end portion of a contact, and a distance from the end portion of the N+ region to a device isolation region outside the N+ region to secure a breakdown voltage and a margin of misalignment of contacts.

Meanwhile, in the low breakdown voltage transistor, impurity ions in the N+ region in the source/drain region diffuse due to a heat treatment process when memory cells are formed and overlap capacitance increases.

In addition, in the high breakdown voltage transistor and the low breakdown voltage transistor, parasitic resistance increases depending on a material of the contact connected to the source/drain region, which results in causing an electrical characteristic of the transistor to be deteriorated.

### BRIEF DESCRIPTION OF THE DRAWINGS

FIG. 1 is a plan view of an HV transistor;

FIG. 2 is a cross-sectional view taken along the line A-A of FIG. 1;

FIG. 3 is a detailed cross-sectional view of a peripheral portion of a shallow trench isolation;

FIG. 4 is a cross-sectional view of an HV transistor according to a comparative example;

FIG. 5 is a plan view of an LV transistor 30;

FIG. 6 is a cross-sectional view taken along the line B-B of FIG. 5;

FIG. 7 is a cross-sectional view of an LV transistor according to a comparative example;

FIGS. 8A and 8B are plan views of modifications of FIGS. 1 and 5; and

FIGS. 9A to 9H are cross-sectional views illustrating manufacturing processes of the HV transistor.

### DETAILED DESCRIPTION

A semiconductor device according to one embodiment has two first semiconductor regions that are arranged at intervals on a surface of a semiconductor substrate, one of the two semiconductor regions being a source region and another of the two semiconductor regions being a drain region, and a contact that extends from at least one of the two first semiconductor regions on the semiconductor substrate. The contact comprises a single-crystal first semiconductor layer arranged to contact the surface of the semiconductor substrate, a compound layer that is arranged on the first semiconductor layer and includes a semiconductor in the first semiconductor layer and a metal, and a metal layer arranged on the compound layer.

A semiconductor device according to an embodiment will be described hereinafter with reference to the drawings. The semiconductor device to be described below is a MOS transistor that is formed on a semiconductor substrate.

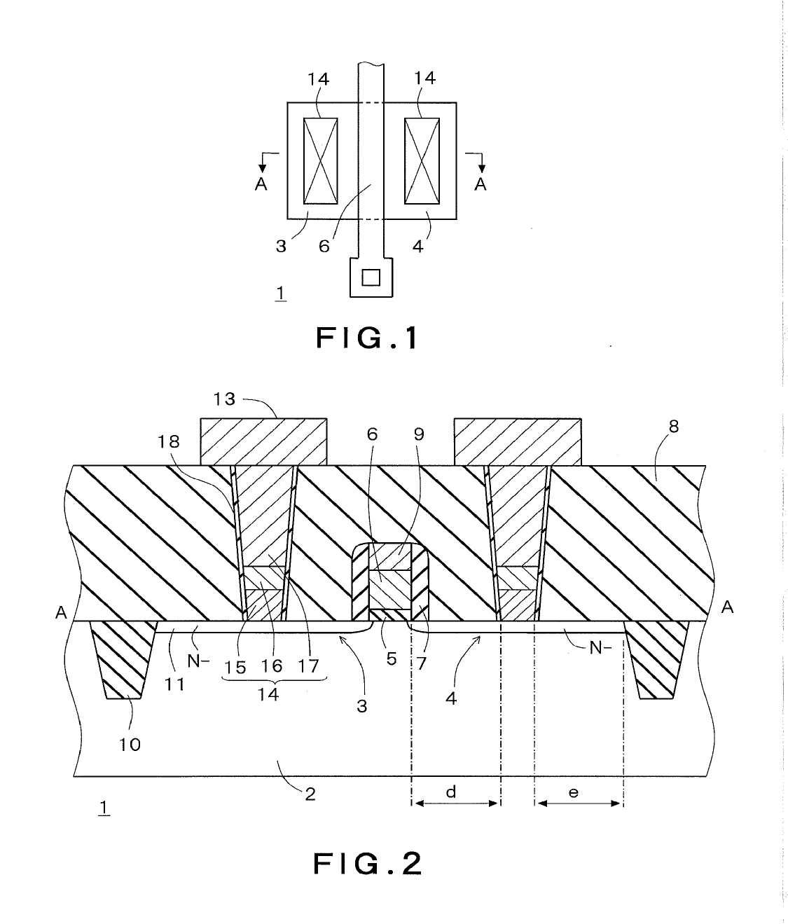

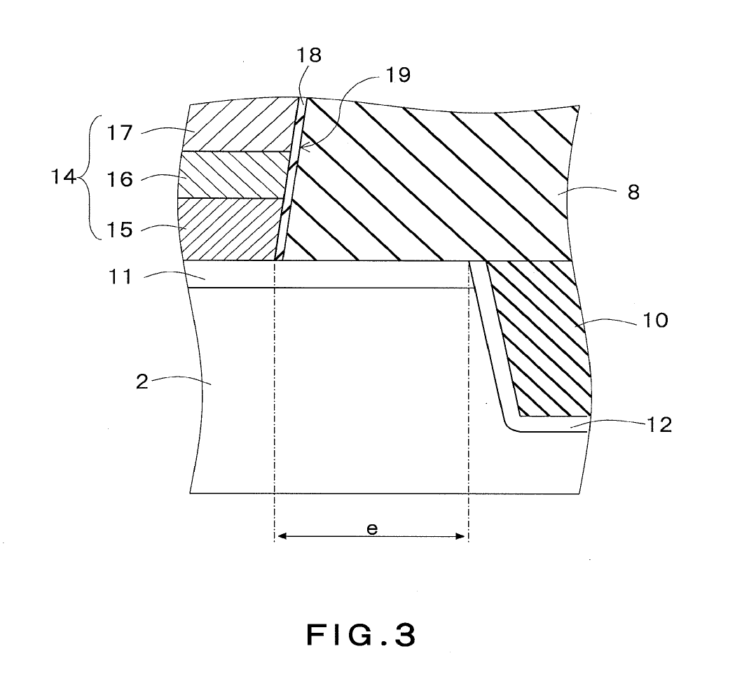

FIGS. 1 and 2 are diagrams illustrating a high breakdown voltage transistor (hereinafter, referred to as an HV transistor) 1 according to an embodiment. FIG. 1 is a plan view of the HV transistor 1 and FIG. 2 is a cross-sectional view taken along the line A-A of FIG. 1.

The HV transistor 1 of FIGS. 1 and 2 is formed in a region isolated by a shallow trench isolation (STI) of a semiconductor substrate. The STI corresponds to a device isolation region. Hereinafter, an example of the case in which a silicon substrate 2 is used as the semiconductor substrate will be explained below.

The HV transistor 1 includes a source region 3 and a drain region 4 that become two first semiconductor regions, a gate insulating film 5 and a gate electrode 6 that are stacked on the silicon substrate 2 between the source region 3 and the drain region 4, and a gate sidewall insulating film 7 that is arranged on sidewall portions of the gate electrode 6 and the gate insulating film 5. Surrounding portions of the gate electrode 6 and the gate sidewall insulating film 7 are covered with an interlayer insulating film 8. A spacer may be formed around the gate sidewall insulating film 7 and the gate electrode 6. However, the spacer is omitted in FIG. 2.

The gate electrode 6 is formed of a plurality of conductive layers, for example. The gate electrode 6 may be formed of one conductive layer. A cap insulating film 9 made of SiN is formed on the gate electrode 6.

The source region 3 and the drain region 4 are arranged along a surface of the silicon substrate 2. A specific conductive well region may be formed in the silicon substrate 2 and the source region 3 and the drain region 4 may be formed in the well region.

FIG. 2 illustrates a cross-sectional structure of the n-type HV transistor 1. However, when a p-type HV transistor is formed, a conductive well region different from the n-type HV transistor 1 may be formed in a region isolated from the n-type HV transistor 1 by the shallow trench isolation and the p-type HV transistor may be formed in the well region.

Each of the source region 3 and the drain region 4 of the HV transistor 1 of FIG. 2 has an N− diffusion region 11 (first semiconductor region) that extends along the surface of the silicon substrate 2, below the gate sidewall insulating film 7, that is, from an end portion of the gate insulating film 5 to a peripheral portion of the shallow trench isolation 10. The N− diffusion region 11 is a region where impurity ions such as As and P are implanted and diffused, for example.

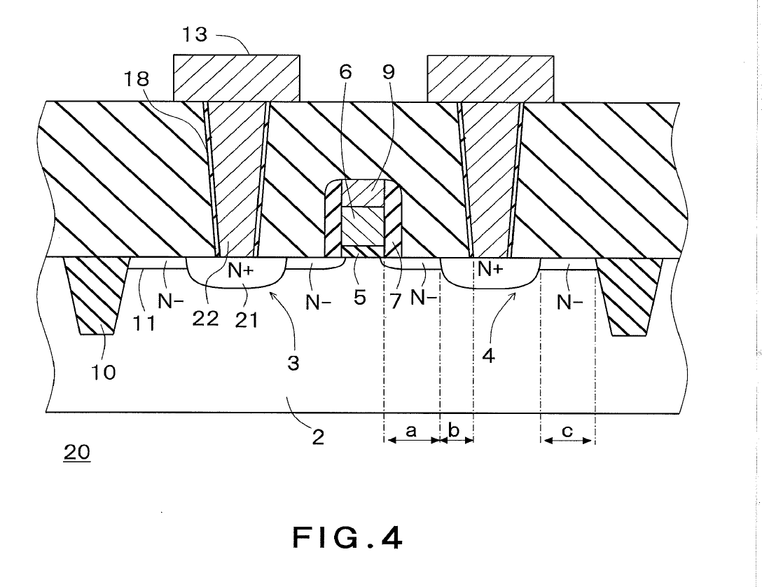

More accurately, as illustrated in FIG. 3, the N− diffusion region 11 reaches a P− diffusion region (second semiconductor region) 12 to cover a lateral surface and a bottom surface of the shallow trench isolation 10. The P− diffusion region 12 is a layer that is formed by diffusing p-type impurities in the shallow trench isolation 10 by heat treatment, when the shallow trench isolation 10 is formed of SiO₂.

A contact 14 for connection with an upper wiring layer 13 is connected to a predetermined position on the N− diffusion region 11. The contact 14 has a single-crystal N+ epitaxial Si layer 15 extending upward from the surface of the silicon substrate 2, a silicide layer 16 arranged on the N+ epitaxial Si layer 15, and a metal layer 17 arranged on the silicide layer 16. Because the contact 14 has a shape of a column extending upward from the semiconductor substrate 2, the contact can be called a contact plug.

The N+ epitaxial Si layer 15, the silicide layer 16, and the metal layer 17 are formed along an inner wall of a contact hole 19 formed in the interlayer insulating film 8 and become a self-alignment structure. Therefore, an area of the contact 14 can be reduced and reduction of a transistor size can be realized.

In FIGS. 2 and 3, a distance e is a distance from a bottom portion edge position of the contact 14 at the side of the shallow trench isolation 10 to an edge position of the shallow trench isolation 10 at the side of the N− diffusion region 11. In the HV transistor 1 according to this embodiment, the distance e is set to a value larger than 0. That is, the bottom portion edge position of the contact 14 at the side of the shallow trench isolation is closer to the side of the gate insulating film 5 than the edge position of the shallow trench isolation 10 at the side of the N− diffusion region 11.

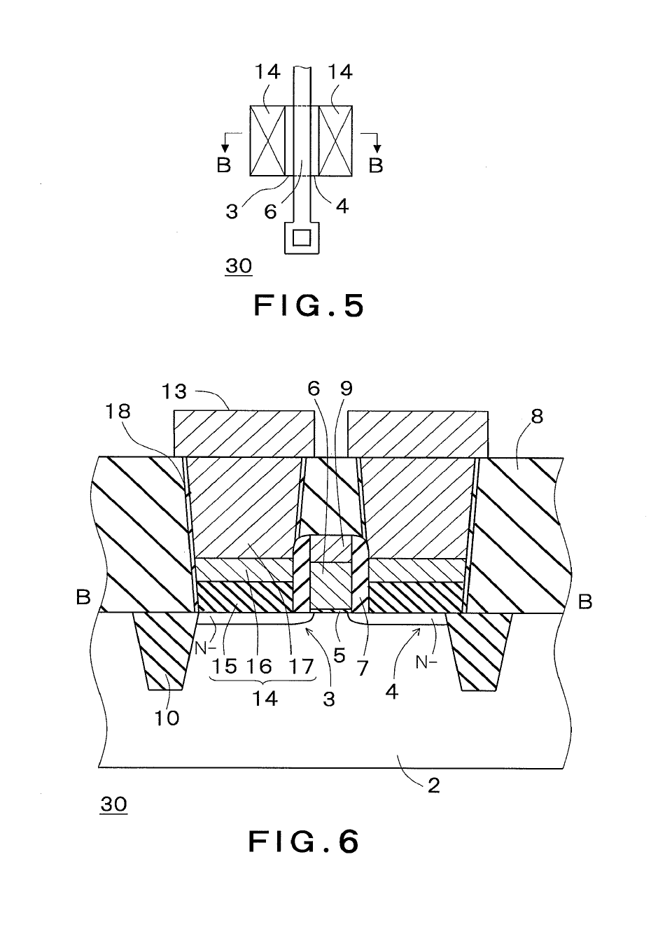

FIG. 4 is a cross-sectional view of an HV transistor 20 according to a comparative example. In the HV transistor 20 of FIG. 4, n-type impurity ions such as As and P are more implanted into a part of an N− diffusion region 11 to form an N+ diffusion region 21 and a contact 22 made of a metal material such as W is connected to the N+ diffusion region 21. In FIG. 4, a distance from a gate insulating film 5 to the N+ diffusion region 21 is set to a, a distance from an end portion of the N+ diffusion region 21 to the contact 22 is set to b, and a distance from the N+ diffusion region 21 to a shallow trench isolation 10 is set to c. Specifically, the distance a is a shortest distance from the end portion of the gate insulating film 5 at the side of the N− diffusion region 11 to the end portion of the N+ diffusion region 21 at the side of the gate insulating film 5. In addition, the distance b is a shortest distance from the end portion of the N+ diffusion region 21 to an end portion of the contact 22. In addition, the distance c is a shortest distance from the end portion of the N+ diffusion region 21 at the side of the shallow trench isolation 10 to the end portion of the shallow trench isolation 10.

In the case of the HV transistor 20 of FIG. 4, because the N+ diffusion region 21 is formed in the N− diffusion region 11, it is necessary to set the distance a greatly with a margin by considering securing of a breakdown voltage and a variation on a manufacturing process. Because the contact 22 of FIG. 4 is formed in the N+ diffusion region 21, it is necessary to set the distance b greatly with a margin by considering the variation on the manufacturing process. The distance c is also the same.

In contrast, in the HV transistor 1 of FIG. 2, the N+ diffusion region 21 is not formed in the source region 3 and the drain region 4 and the distance (first distance) d from the contact 14 in the N− diffusion region 11 to the gate insulating film 5 and the distance (second distance) e from the contact 14 to the shallow trench isolation 10 are conditions for securing of the breakdown voltage. In FIGS. 2 and 4, when widths of the contacts 14 and 22 are the same, a width of the N+ diffusion region 21 of FIG. 4 becomes larger than a width of the contact 14 of FIG. 2. Therefore, the distances d and e of FIG. 2 are larger than the distances a and c of FIG. 4 and the breakdown voltage of the HV transistor 1 of FIG. 2 is higher than the breakdown voltage of the HV transistor 20 of FIG. 4. In FIG. 2, because the distances d and e can be decreased to secure the same breakdown voltage as the breakdown voltage of FIG. 4, a size of the HV transistor 1 can be reduced.

As such, because a restriction of the HV transistor 1 of FIG. 2 for the breakdown voltage is less than a restriction of the HV transistor 20 of FIG. 4 for the breakdown voltage, the HV transistor 1 can have a structure of a high breakdown voltage, and reduction of the transistor size of the HV transistor 1 can be realized.

In the NAND-type flash memory, the HV transistor 1 illustrated in FIGS. 1 and 2 is used for a word line driver connected to a word line or a transistor to control connection of a bit line and a sense amplifier. Meanwhile, in a NAND-type flash memory, multiple low breakdown voltage transistors are used in a memory cell transistor or a controller.

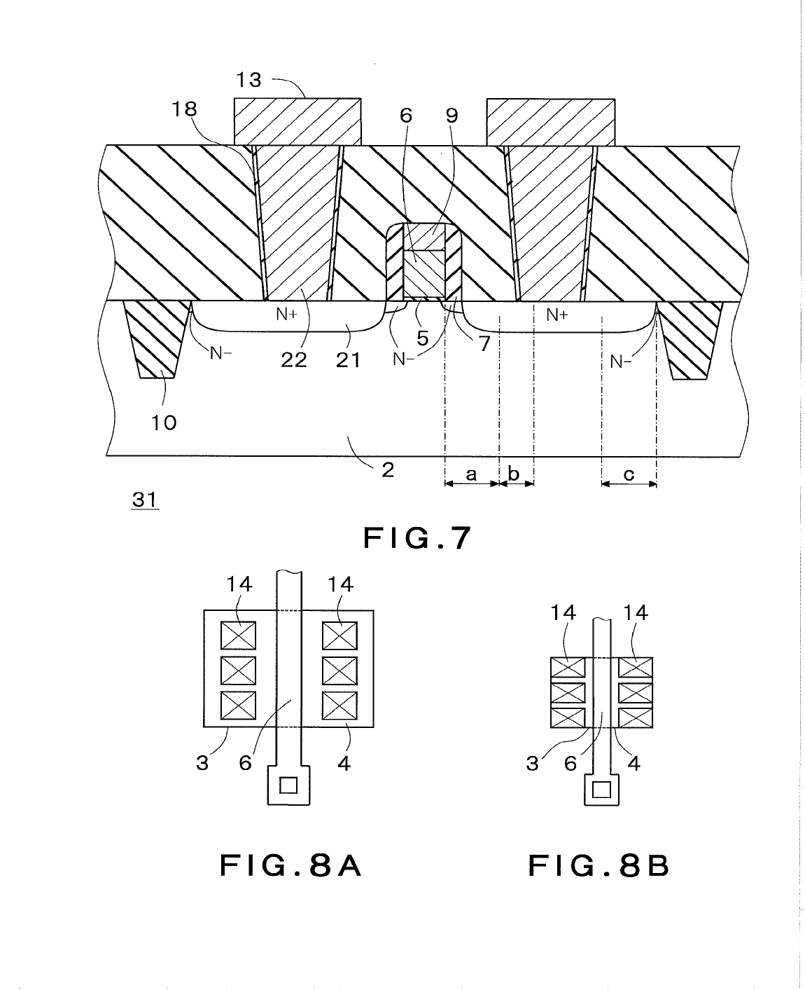

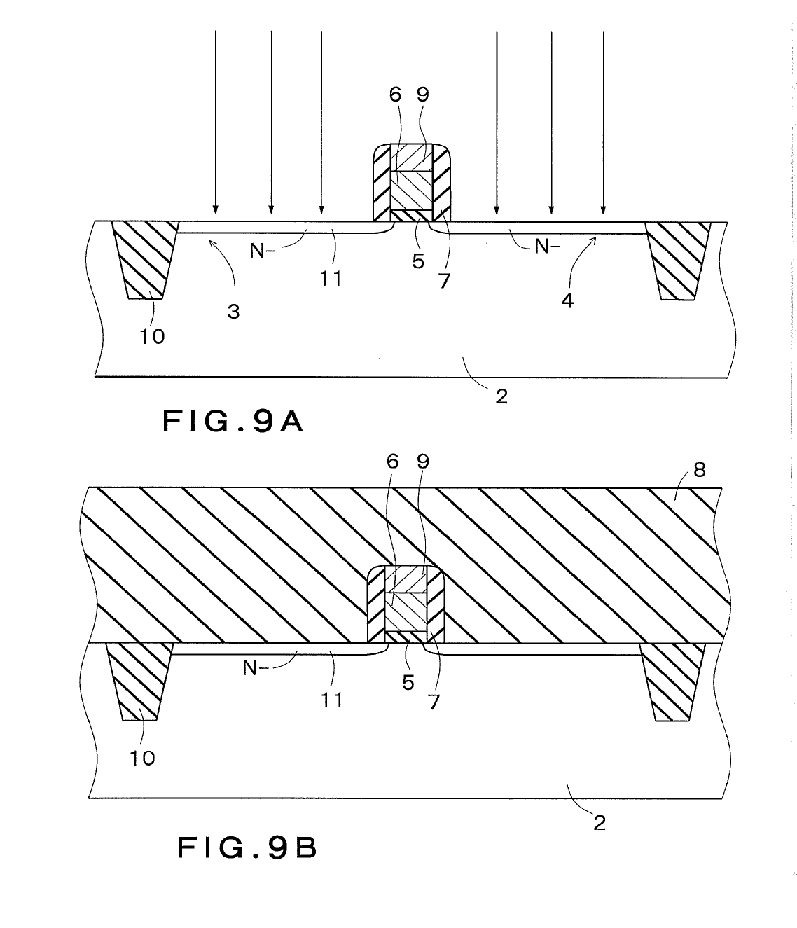

FIGS. 5 and 6 are diagrams illustrating a low breakdown voltage transistor (hereinafter, referred to as an LV transistor) 30 according to an embodiment. FIG. 5 is a plan view of the LV transistor 30 and FIG. 6 is a cross-sectional view taken along the line B-B of FIG. 5.

The LV transistor 30 illustrated in FIGS. 5 and 6 is arranged in a region isolated by a shallow trench isolation 10 on a silicon substrate 2, similar to the HV transistor 1 illustrated in FIGS. 1 and 2. Similar to the HV transistor 1, the LV transistor 30 has a source region 3, a drain region 4, a gate insulating film 5, a gate electrode 6, and a gate sidewall insulating film 7 and a contact 14 penetrating an interlayer insulating film 8 is connected to each of the source region 3 and the drain region 4. The source region 3 and the drain region 4 in the present specification are regions functioning as a source and a drain of one transistor. Specifically, the source region 3 and the drain region 4 are regions where the same potentials are set from a source electrode and a drain electrode via one or more contacts. The source region 3 and the drain region 4 are formed in the vicinity of the surface of the semiconductor substrate 2.

As seen from comparison of FIGS. 5 and 1, a ratio of areas of the contacts 14 to areas of the source region 3 and the drain region 4 of the LV transistor 30 is larger than a ratio in the HV transistor 1. This reason is as follows. In the LV transistor 30, because a high breakdown voltage is not required, a distance from the gate insulating film 5 to the contact 14 and a distance from the contact 14 to the shallow trench isolation 10 can be shortened.

In addition, in the LV transistor 30, because the high breakdown voltage is not required, a thickness of the gate insulating film 5 is smaller than a thickness of the gate insulating film in the HV transistor 1.

In addition, an entire transistor size of the LV transistor 30 is smaller than an entire transistor size of the HV transistor 1.

Similarly to the contact 14 of FIG. 2, the contact 14 of FIG. 6 has the N+ epitaxial Si layer 15 formed on the surface of the silicon substrate 2, the silicide layer (compound layer) 16 arranged thereon, and the metal layer 17 arranged thereon.

In FIG. 6, the contacts 14 connected to the source region 3 and the drain region 4 are contacted with the gate sidewall insulating film 7 and the shallow trench isolation 10 to minimize the size of the LV transistor 30.

In detail, at the side of the source region 3 in FIG. 6, an insulating film 18 of a sidewall portion of the contact 14 contacts the shallow trench isolation 10. In this case, an entire bottom surface of the contact 14 at the side of the source region 3 contacts the N− diffusion region 11 and the N+ epitaxial Si layer 15 having the uniform film thickness is grown in the contact 14. Meanwhile, at the side of the drain region 4 in FIG. 6, a part of the bottom surface of the contact 14 overlaps the shallow trench isolation 10. In this case, in a place where the contact 14 and the shallow trench isolation 10 overlap, a progress of the epitaxial growth is moderated and the film thickness of the N+ epitaxial Si layer 15 at the side of the gate insulating film 5 becomes larger than the film thickness at the side of the shallow trench isolation 10. Even though the film thickness of the silicide layer 16 formed on the N+ epitaxial Si layer 15 is uniform, the height of the top surface of the silicide layer 16 at the side of the shallow trench isolation 10 is smaller than the height at the side of the gate insulating film 5.

The configuration of FIG. 6 is only exemplary and the contact 14 of the LV transistor 30 may be arranged not to contact the gate sidewall insulating film 7 and the shallow trench isolation 10 and the contact 14 may be arranged to contact only one of the gate sidewall insulating film 7 and the shallow trench isolation 10.

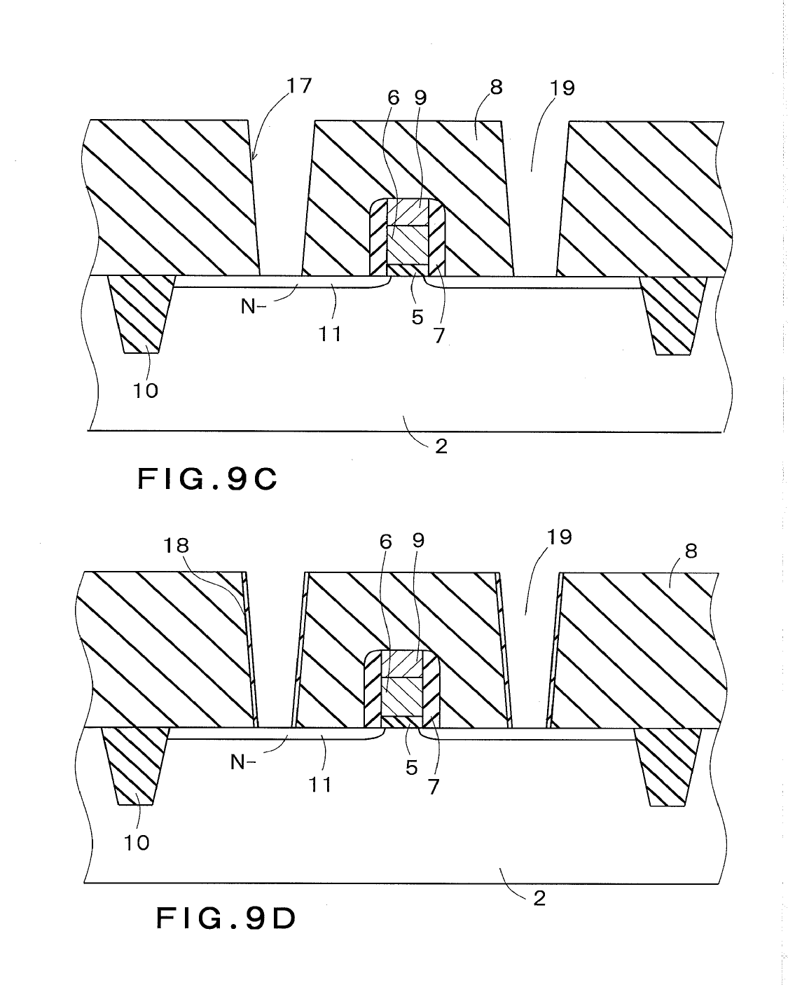

FIG. 7 is a cross-sectional view of an LV transistor 31 according to a comparative example. Each of a source region 3 and a drain region 4 of the LV transistor 31 of FIG. 7 has an N− diffusion region 11 formed below a gate sidewall insulating film 7, an N+ diffusion region 21 formed on a surface of a silicon substrate 2 from the gate sidewall insulating film 7 to a shallow trench isolation 10, and a contact 22 connected to the N+ diffusion region 21. The contact 22 of FIG. 7 is formed of a metal material such as W.

When a memory cell is formed after the LV transistor 31 of FIG. 7 is formed, impurity ions in the N+ diffusion region 21 are diffused by a heat treatment process at the time of a memory cell manufacturing process and overlap capacitance increases.

In contrast, in the LV transistor 30 of FIG. 6, because the N+ diffusion region 21 is not formed, the overlap capacitance does not increase.

In both the HV transistor 1 of FIG. 2 and the LV transistor 30 of FIG. 6, silicide is provided in the contact 14. As a result, parasitic resistance of the contact 14 can be reduced and an electrical characteristic of the transistor can be improved.

In the HV transistor 20 and the LV transistor 31 according to the comparative examples of FIGS. 4 and 7, because the memory cell is formed before the contact 22 is formed, the heat treatment process is executed at the time of forming the memory cell and the silicide cannot be formed in the source/drain region. However, because the contact 14 for the HV transistor 1 and the LV transistor 30 of FIGS. 2 and 6 is formed after forming the memory cell as described below, the silicide can be formed in the contact 14. As a result, in the HV transistor 1 and the LV transistor 30 of FIGS. 2 and 6, the parasitic resistance of the contact 14 can be reduced and the electrical characteristic of the transistor can be improved, as compared with the transistors of FIGS. 4 and 7.

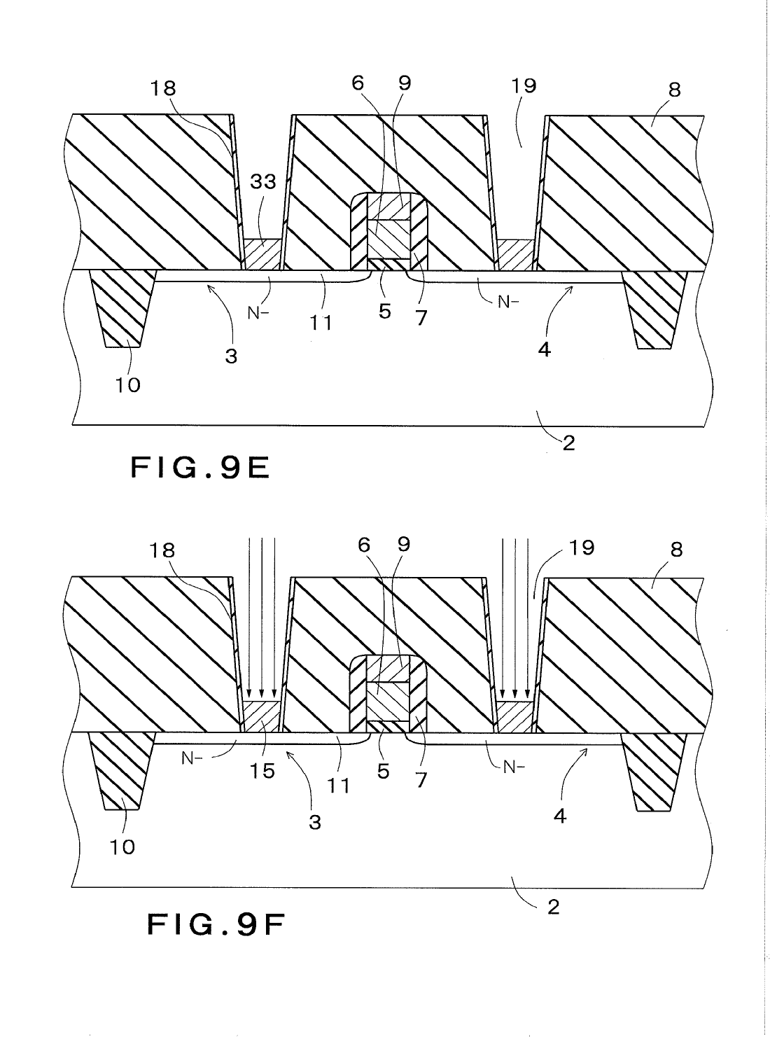

In FIGS. 1 and 5, one contact 14 is provided in each of the source region 3 and the drain region 4. As illustrated in FIGS. 8A and 8B, the plurality of contacts 14 may be provided in at least one of the source region 3 and the drain region 4. FIG. 8A illustrates an example of the case in which the plurality of contacts 14 are provided in each of the source region 3 and the drain region 4 of the HV transistor 1 and FIG. 8B illustrates an example of the case in which a plurality of contacts 14 are provided in each of the source region 3 and the drain region 4 of the LV transistor 30. A ratio of areas of the plurality of contacts 14 to areas of the source region 3 and the drain region 4 in FIG. 8A is smaller than a ratio in FIG. 8B.

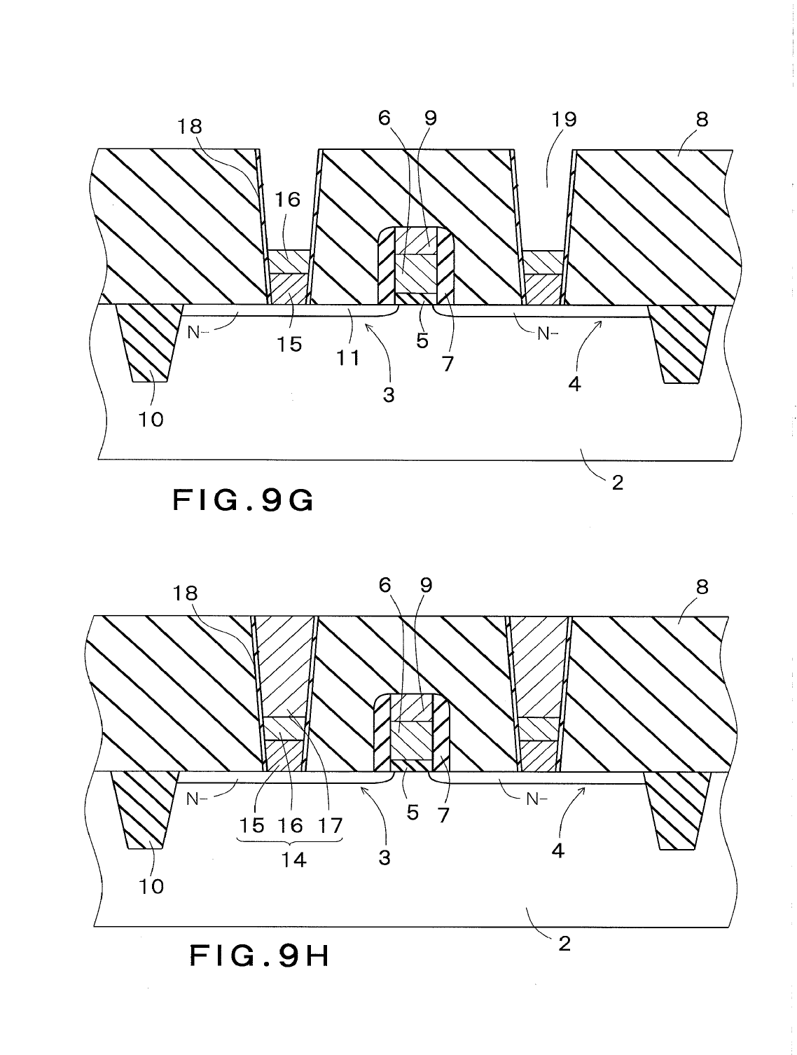

Next, a method of manufacturing the HV transistor 1 according to this embodiment will be explained below. FIGS. 9A to 9H are cross-sectional views illustrating an example of manufacturing processes of the HV transistor 1. The HV transistor 1 and the LV transistor 30 can be manufactured in parallel by common manufacturing processes.

First, as illustrated in FIG. 9A, the gate insulating film 5, the gate electrode 6, and the gate sidewall insulating film 7 are formed on the silicon substrate 2. Then, the n-type impurity ions are implanted into the entire region of the source region 3 and the drain region 4, the heat treatment is performed at a predetermined temperature, and the N− diffusion region 11 (lightly doped drain (LDD) region) extended from the gate sidewall insulating film 7 to the shallow trench isolation 10 is formed.

Next, as illustrated in FIG. 9B, the surrounding portions of the gate electrode 6 and the gate sidewall insulating film 7 are covered with the interlayer insulating film 8. The interlayer insulating film 8 is formed of SiO₂, for example. In the HV transistor 1 and the LV transistor 30, the thickness of the gate insulating film 5 is different and the transistor size is also often different. Therefore, in the process of FIG. 9A, each film is formed to have the film thickness and the size meeting a design condition of each of the HV transistor 1 and the LV transistor 30.

In this embodiment, because the silicide is used in the contacts 14 connected to the source region 3 and the drain region 4 of the HV transistor 1 and the LV transistor 30, at least the formation process of the contact 14 needs to be executed after the heat treatment process of the memory cell at the high heat ends. For example, manufacturing of the memory cell including the heat treatment process at the high heat is performed after formation of the gate insulating film 5, the gate electrode 6, and the gate sidewall insulating film 7 of FIG. 9A ends. Then, a process after formation of the interlayer insulating film 8 of FIG. 9A is executed.

If the process of FIG. 9B ends, as illustrated in FIG. 9C next, the contact hole 19 penetrating formation places of the source region 3 and the drain region 4, that is, the N− diffusion layer 11 is formed in the interlayer insulating film 8. As illustrated in FIGS. 8A and 8B, the plurality of contact holes 19 may be provided in each of the source region 3 and the drain region 4.

In the HV transistor 1, a formation place of the contact hole 19 is important. This is because the distance d from the contact 14 formed in the contact hole 19 by the following process to the gate insulating film 5 needs to satisfy the condition of securing of the breakdown voltage and the distance e from the contact 14 to the shallow trench isolation 10 needs to satisfy the condition of securing of the breakdown voltage. Therefore, in the process of FIG. 9B, the contact hole 19 is formed at the position satisfying the conditions.

In the HV transistor 1 and the LV transistor 30, a ratio of areas of the contacts 14 to areas of the source region 3 and the drain region 4 is different. Therefore, in the HV transistor 1 and the LV transistor 30, it is necessary to change the formation place and the size of the contact hole 19 and the number of contact holes 19 is changed according to a situation.

Next, as illustrated in FIG. 9D, an inner wall surface of the contact hole 19 is covered with the insulating film 18. The insulating film 18 is formed of silicon nitride (SiN), for example.

Meanwhile, in the LV transistor 30, the gate sidewall insulating film 7 is covered with the interlayer insulating film by the process of FIG. 9A. Next, the contact hole 19 is formed, the inner wall of the contact hole 19 is covered with the insulating film 18, the n-type impurity ions are implanted into the source region 3 and the drain region 4 via the contact hole 19, the heat treatment is performed, and the N− diffusion region 11 extended from the gate sidewall insulating film 7 to the shallow trench isolation 10 is formed. As such, in the HV transistor 1 and the LV transistor 30, formation order of the contact hole 19 and the N− diffusion layer 11 is reverse and a method of implanting the impurity ions is also different.

After the gate sidewall insulating film is formed, the ions are implanted into the entire surface of the source/drain region to form the N− diffusion layer. Then, the interlayer insulating film is deposited and formed and the contact hole is formed.

Next, as illustrated in FIG. 9E, at a predetermined temperature and a single-crystal silicon layer 33 having the same plane orientation as the N− diffusion region 11 is epitaxially grown in the contact hole 19.

Next, as illustrated in FIG. 9F, the n-type impurity ions are implanted into the contact hole 19 using a plasma doping method to cause the epitaxially grown single-crystal epitaxial Si layer 33 to become the N+ epitaxial Si layer 15.

Next, as illustrated in FIG. 9G, a metal material such as Ni is adhered to the surface of the N+ epitaxial Si layer 15 in the contact hole 19, the heat treatment is performed at the predetermined temperature, and the silicide layer 16 is formed.

Next, as illustrated in FIG. 9H, the metal layer 17 such as W is formed on the surface of the silicide layer 16 in the contact hole 19. In this way, the contact 14 having the N+ epitaxial Si layer 15, the silicide layer 16, and the metal layer 17 can be formed in the contact hole 19 by self alignment. Then, a wiring layer is formed in the contact 14 and the cross-sectional structure of FIG. 2 is obtained.

In FIGS. 9A to 9H, the manufacturing processes of the HV transistors 1 are illustrated. In the LV transistor 30, because the ratio of the areas of the contacts 14 to the areas of the source region 3 and the drain region 4 is different, the formation place of the contact hole 19 is different from the formation place in FIG. 9 and the thickness of the gate insulating film 5 is smaller than the thickness of the gate insulating film in the HV transistor 1 of FIGS. 9A to 9H. However, basic process order or a layer configuration of the contact 14 is the same as that in FIGS. 9A to 9H and the HV transistor 1 and the LV transistor 30 can be manufactured by the common manufacturing processes, as described above.

As such, in this embodiment, because the N+ diffusion regions 21 are provided in the contacts 14 extending upward from the N− diffusion regions 11 in the source region 3 and the drain region 4, the distance from the contact 14 to the gate insulating film 5 and the distance from the contact 14 to the shallow trench isolation 10 can be set with the margin and the breakdown voltage can be improved, as compared with the case in which the N+ diffusion region 21 is provided in a part of the N− diffusion region 11 and the contact 14 is connected to a part of the N+ diffusion region 21. If the contact 14 according to this embodiment is provided, the distance between the gate insulating film 5 and the contact 14 and the distance between the contact 14 and the shallow trench isolation 10 can be shortened. Therefore, reduction of the transistor size can be realized.

For example, in the NAND-type flash memory, the high breakdown voltage transistor is essential. For this reason, according to this embodiment, the high breakdown voltage transistor can be manufactured without increasing the transistor size.

In addition, in the NAND-type flash memory, the low breakdown voltage transistor is also essential. However, according to this embodiment, because the N+ diffusion region 21 may not be provided in the source region 3 and the drain region 4, a failure does not occur fundamentally, where the impurity ions in the N+ diffusion region 21 diffuse in the N− diffusion region 11 and the overlap capacitance increases.

In this embodiment, because the contact 14 is formed after the heating process at the time of forming the memory cell, the silicide can be provided in the contact 14, the parasitic resistance of the contact 14 can be reduced, and the electrical characteristic of the transistor can be improved.

In the embodiment described above, the contact 14 illustrated in FIG. 2 or 5 is connected to both the source region 3 and the drain region 4. However, the contact 14 illustrated in FIG. 2 or 5 may be connected to one of the source region 3 and the drain region 4 and the contact 22 illustrated in FIG. 3 or 6 may be connected to the other of the source region 3 and the drain region 4.

In the embodiment described above, the high breakdown voltage transistor and the low breakdown voltage transistor used by the NAND-type flash memory have been described as the example. However, this embodiment can be applied to various transistors other than the NAND-type flash memory.

Some embodiments of the present invention have been described. However, the embodiments are only exemplary and do not limit the range of the invention. New embodiments can be carried out in a variety of other forms and various omissions, replacements, and changes can be made without departing from the scope of the invention. The embodiments and the modifications are included in the range and the scope of the invention and are included in a range equivalent to the range of the invention.

1. A semiconductor device comprising:
two first semiconductor regions that are arranged at intervals on a surface of a semiconductor substrate, one of the two semiconductor regions being a source region and another of the two semiconductor regions being a drain region; and
a contact that extends from at least one of the two first semiconductor regions on the semiconductor substrate,
wherein the contact comprises a single-crystal first semiconductor layer arranged to contact the surface of the semiconductor substrate, a compound layer that is arranged on the first semiconductor layer and includes a semiconductor in the first semiconductor layer and a metal, and a metal layer arranged on the compound layer.

2. The semiconductor device according to claim 1,
wherein the semiconductor substrate and the first semiconductor layer have the same plane orientation.

3. The semiconductor device according to claim 1, further comprising:
a gate sidewall insulating film arranged on lateral surfaces of a gate insulating film and a gate electrode,
wherein the contact is arranged at a position that does not contact the gate sidewall insulating film.

4. The semiconductor device according to claim 3, further comprising:
a gate insulating film and a gate electrode that are stacked on the semiconductor substrate between the two first semiconductor regions,
wherein the contact is arranged at a position isolated from an end of the first semiconductor region at the side of the gate insulating film along the surface of the semiconductor substrate, by a first distance or more.

5. The semiconductor device according to claim 3, further comprising:
a device isolation region that electrically isolates device formation regions in the two first semiconductor regions from the semiconductor substrate,
wherein a bottom portion edge position of the contact at the side of the device isolation region is closer to the side of the gate insulating film than an edge position of the device isolation region at the side of the first semiconductor region.

6. The semiconductor device according to claim 5, further comprising:
second semiconductor regions that are arranged to contact a lateral surface and a bottom surface of the device isolation region and are connected to the first semiconductor regions,
wherein the contact is arranged to be closer to the side of the gate insulating film than the second semiconductor region.

7. The semiconductor device according to claim 6,
wherein the contact is arranged at a position isolated from a boundary position of the first semiconductor region and the second semiconductor region, in a direction of the gate insulating film along the surface of the semiconductor substrate, by a second distance or more.

8. The semiconductor device according to claim 1, further comprising:
a gate insulating film and a gate electrode that are stacked on the semiconductor substrate between the two first semiconductor regions; and
a gate sidewall insulating film arranged on lateral surfaces of the gate insulating film and the gate electrode,
wherein a part of the contact at the side of the gate insulating film is arranged to overlap the gate sidewall insulating film.

9. The semiconductor device according to claim 1, further comprising:
a device isolation region that electrically isolates device formation regions in the two first semiconductor regions from the semiconductor substrate,
wherein a part of the contact at the side of the device isolation region is arranged to overlap the device isolation region.

10. The semiconductor device according to claim 9, further comprising:
a gate insulating film and a gate electrode that are stacked on the semiconductor substrate between the two first semiconductor regions,
wherein a thickness of the first semiconductor layer in the contact at the side of the device isolation region is smaller than a thickness of the first semiconductor layer at the side of the gate insulating film.

11. The semiconductor device according to claim 3, further comprising:
a first transistor that comprises the two first semiconductor regions, the contact, the gate insulating film, and the gate electrode; and
a second transistor that is arranged on the semiconductor substrate to be isolated from the first transistor and comprises two first semiconductor regions different from the two first semiconductor regions of the first transistor, the contact, the gate insulating film, and the gate electrode,
wherein, in the first transistor, a thickness of the gate insulating film is large and a ratio of an area of the contact to an area of the first semiconductor region is small, as compared with the second transistor.

12. A method of manufacturing a semiconductor device, comprising:
forming two first semiconductor regions of which one is for a source region and another is for a drain region on a surface of a semiconductor substrate, stacking a gate insulating film and a gate electrode on the semiconductor substrate between the two first semiconductor regions, and forming a device isolation region to electrically isolate device formation regions in the two first semiconductor regions from the semiconductor substrate;
forming a contact hole penetrating an interlayer insulating film and reaching at least one of the two first semiconductor regions in the interlayer insulating film;
epitaxially growing a single-crystal first semiconductor layer in the contact hole;
performing heat treatment after adhering a metal to the first semiconductor layer in the contact hole and forming a compound layer including a semiconductor in the first semiconductor layer and the metal on the first semiconductor layer; and
forming a metal layer on the compound layer in the contact hole.

13. The method according to claim 12,
wherein the first semiconductor layer, the compound layer, and the metal layer in the contact hole are formed by self alignment along an inner wall of the contact hole.

14. The method according to claim 12, further comprising:
implanting impurity ions into a surface of the first semiconductor region via the contact hole to form a lightly doped drain (LDD) region,
wherein the first semiconductor layer is epitaxially grown in the contact hole after the LDD region is formed.

15. The method according to claim 12,
wherein the first semiconductor layer is a single-crystal epitaxial semiconductor layer that has a plane orientation aligned with a plane orientation of the first semiconductor region.

16. The method according to claim 12,
wherein the contact hole is formed at a position where the contact hole does not contact a gate sidewall insulating film arranged on lateral surfaces of the gate insulating film and the gate electrode.

17. The method according to claim 12,
wherein the contact hole is formed to be closer to the side of the gate insulating film than the device isolation region, such that the contact hole does not contact the device isolation region to electrically isolate the device formation regions in the two first semiconductor regions from the semiconductor substrate.

18. The method according to claim 17,
wherein the contact hole is formed to be closer to the side of the gate insulating film than second semiconductor regions that contact a lateral surface and a bottom surface of the device isolation region and are connected to the first semiconductor regions.

19. The method according to claim 12,
wherein the contact hole is formed to contact a gate sidewall insulating film arranged on a lateral surface of the gate electrode.

20. The method according to claim 12,
wherein the contact hole is formed to contact the device isolation region to electrically isolate the device formation regions in the two first semiconductor regions from the semiconductor substrate.
